(19) United States
(12) Patent Application Publication
(10) Pub. No.: US 2010/0081065 A1
(43) Pub. Date: Apr. 1, 2010

(54) PHOTOMASK AND METHOD OF FABRICATING A PHOTOMASK

(75) Inventors: Dong-Hsu Cheng, Tainan City (TW); Chein-Hao Huang, Hsinchu City (TW); Cheng-Ming Lin, Siluo Township (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/243,311

(22) Filed: Oct. 1, 2008

(51) Int. Cl. G03F 1/00

(52) U.S. Cl. 430/5

(57) ABSTRACT

A method of fabricating a photomask is provided. A masking layer (e.g., chrome) is deposited on a substrate. A plasma treatment may be performed on the chrome layer. A photoresist layer may be formed on the treated chrome layer. In an embodiment, the plasma treatment roughens the chrome layer. In an embodiment, the plasma treatment forms a barrier film on the chrome layer. The photoresist layer may be used to pattern a sub-resolution assist feature.

### BACKGROUND

In semiconductor fabrication, photomasks are used to define patterns that will be printed on a substrate such as a semiconductor wafer, during the photolithography process. However, variations in the intended pattern may be induced by optical interference and other effects. To prevent these effects, sub-resolution assist features (SRAFs) are included on photomasks as an application of resolution enhancement techniques (RET) and in particular, optical proximity correction (OPC). SRAFs may increase the imaging resolution of a main feature (e.g., a feature to be imaged onto a substrate) with which they are associated.

Sub-resolution assist features include narrow lines of material typically placed adjacent a main feature. A plurality of SRAFs may be associated with a main feature. SRAFs are also known in the art as scattering bars. As SRAFs, scattering bars, are not intended to be imaged on the wafer, their size is very small. Furthermore, as the size of main patterns of an IC shrink, so must the SRAFs. Thus, control of SRAFs, in particular with smaller technology node process, becomes difficult.

As such, an improved photomask including SRAFs and method of fabrication thereof is desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a top view of an embodiment of a layout of a photomask including a main feature and a plurality of SRAFs.

FIG. 2 illustrates a cross-sectional view of an embodiment of a photomask.

FIG. 3 illustrates a cross-sectional view of a conventional embodiment of a photomask including a photoresist feature.

FIG. 4 illustrates a flow chart of an embodiment of a method of providing a photomask.

FIG. 5 illustrates a flow chart of an embodiment of a method of providing a photomask including formation of a barrier film.

FIG. 6 illustrates a cross-sectional view of an embodiment of a photomask including a barrier film.

FIG. 7 illustrates a cross-sectional view of an embodiment of a photomask including a photoresist feature formed on a barrier film.

### DETAILED DESCRIPTION

The present disclosure relates generally to photolithography, and more particularly, to a sub-resolution assistant feature (SRAF) provided on a photomask used in fabrication of semiconductor devices. It is understood, however, that specific embodiments are provided as examples to teach the broader inventive concept, and one of ordinary skill in the art can easily apply the teaching of the present disclosure to other methods or apparatus. For example, though described herein as providing a photomask for fabrication of semiconductor devices, any photolithography process may benefit from the disclosure, for example, glass substrate photomask used to form a thin film transistor liquid crystal display (TFT-LCD) substrate. In addition, it is understood that the methods and apparatus discussed in the present disclosure include some conventional structures and/or processes. Since these structures and processes are well known in the art, they will only be discussed in a general level of detail. Furthermore, reference numbers are repeated throughout the drawings for sake of convenience and example, and such repetition does not indicate any required combination of features or steps throughout the drawings. Finally, though described herein as providing a method and apparatus for improved adhesion of a photoresist feature associated with SRAF, the structures and/or processes described herein may provide benefit for formation of a photoresist feature or pattern associated with a feature, including a main feature.

The semiconductor fabrication process requires numerous photolithography steps in which an image (e.g., a pattern) formed on a photomask is projected onto a photosensitive film on a substrate (e.g., a semiconductor wafer). As pattern dimensions decrease, interference and processing effects that occur during the radiation of the image can negatively influence the pattern formed on the wafer. In other words, the pattern formed on the wafer may not be an accurate or adequate reproduction of the pattern designed and formed on the photomask. Resolution enhancement techniques (RET) including optical proximity correction (OPC) are used to more accurately reproduce the pattern. Such techniques may include providing RET features on the mask. RET features include sub-resolution assist features (SRAF) that will not be printed on the wafer, but are placed adjacent a feature that is to be imaged onto a wafer (e.g., a main feature) to improve its imaging. The SRAFs may allow a photolithography process to sharpen and more accurately reproduce the main feature and/or provide for a wider process window (e.g., allowed deviation in lithography parameters) used to image a main feature.

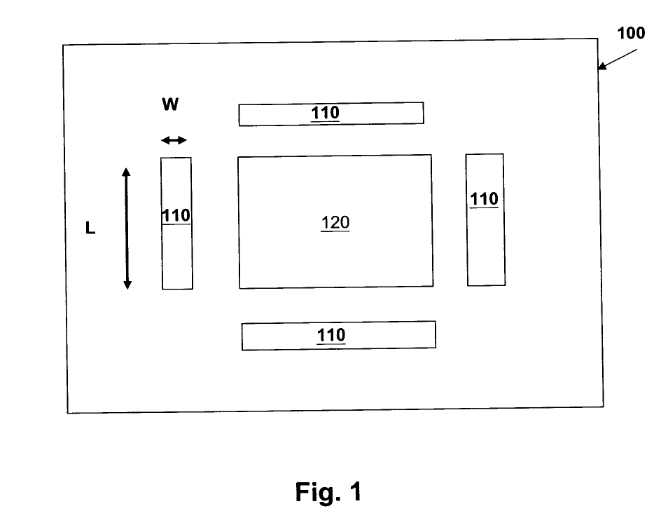

FIG. 1 illustrates a photomask 100. The photomask 100 includes a plurality of sub-resolution assist feature (SRAF) 110 associated with a main feature 120. In an embodiment, the photomask 100 is a binary mask. Other examples of mask technologies that may be included on the photomask 100 are phase-shift masks including attenuated phase shift mask (attPSM), alternating phase shift masks (attPSM), and/or other photomask types known in the art. The photomask 100 includes a substrate. The substrate may be a transparent substrate such as fused silica (SiO₂), or quartz, relatively free of defects; calcium fluoride; or other suitable material. The main feature 120 may be designed to form a portion of an integrated circuit pattern on a semiconductor substrate, such as a wafer. The main feature 120 may be designed to form an integrated circuit feature such as a contact (e.g., via), an insulative region, a conductive line, a source and/or drain, a gate, a doped region, and/or other possible features. The main feature 120 may be formed of a masking layer including attenuating material disposed on the photomask. The masking layer (e.g., attenuating material) may include chrome or other materials such as, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. The main feature 120 may be formed using processes including photoresist deposition, soft baking, mask aligning, exposing (e.g., patterning), baking, developing the photoresist, hard baking, stripping the resist, and/or other processes. In alternative embodiments, the lithography patterning may include electron-beam writing, ion-beam writing, mask-less lithography, and/or molecular imprint. Though illustrated as a symmetrical and rectangular feature, the main feature 120 may be of any shape, size, or dimension.

The SRAF 110 includes a dimension (e.g., W) less than the resolution of the imaging system used with the mask. That is the SRAF 110 is of dimensions such that the feature will not image onto a semiconductor substrate (e.g., wafer) when the mask is irradiated. The SRAF 110 may be formed of attenuating material. In an embodiment, the SRAF 110 is chrome. Other embodiments may include SRAF 100 including other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination thereof. Though illustrated as symmetrical and rectangular, the SRAF 110 may include any variation of shape, size, and/or dimension. In an embodiment, the SRAF 110 is between approximately 0.4 and 0.9 times the minimum pattern size for a given geometry (e.g., the resolution limit of the fabrication process generation or technology node). In an embodiment, the SRAF 110 includes a rectangular shape including dimensions having a ratio (e.g., a W/L ratio) between approximately 2/5 and 1/5. The W/L ratio of a SRAF included on a photomask may decrease as technology node associated with the mask shrinks. For example, in a 90 nm technology node a W/L may be approximately 1/2.5 where in a 45 nanometer technology node the W/L ratio may be 1/5. Thus, as the technology node shrinks it may become more difficult to control SRAF fabrication and use of photomask including SRAFs. Such issues may include defects such as peeling of a SRAF from the photomask.

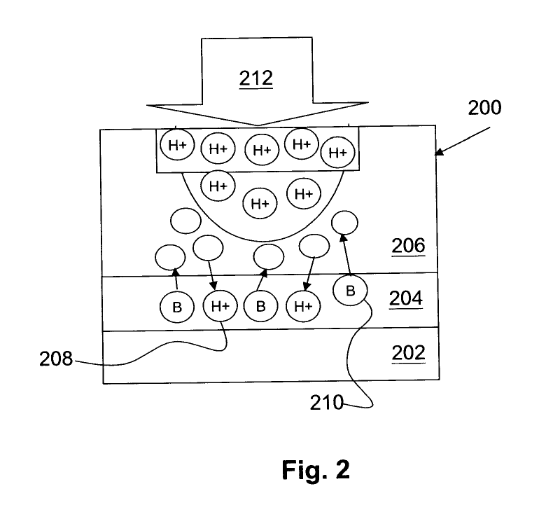

Referring now to FIG. 2, illustrated is a conventional photomask 200. The photomask 200 includes a substrate 202, a chrome layer 204, and a chemical amplification resist (CAR) layer 206. An exposure beam 212 is incident on the photomask 200 and in particular the CAR layer 206. The exposure beam 212 provides for patterning of the CAR layer 206. The pattern may be associated with (e.g., provide a masking element to define) a SRAF. The photomask 200 illustrates acid diffusion to the bottom (e.g., towards the interface of the chrome layer 204) of the CAR layer 206. Note, acid is represented by H+ and base by B. This diffusion may cause acid 208 of the CAR layer 206 diffuse to the chrome layer 204. The photomask 200 also illustrates the quenching of acid in the CAR layer 206 by a base 210 diffusing from the chrome layer 204 to the CAR layer 206. The base 210 may be base contamination found in the nitrogen-rich chrome layer 204. Though illustrated as a negative tone CAR layer 206, issues may also occur in positive tone resist.

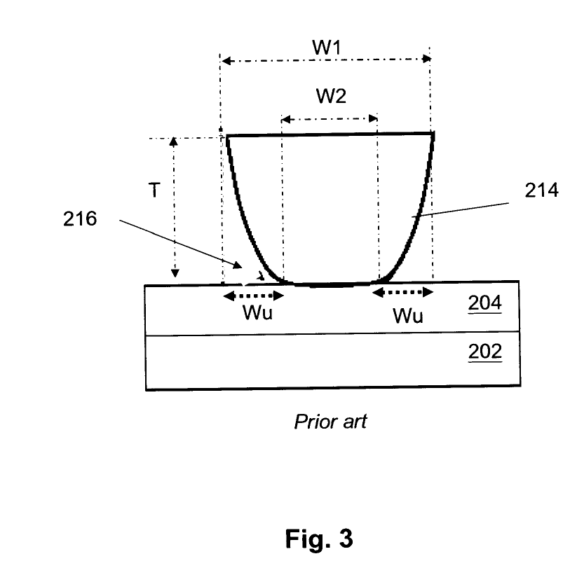

FIG. 3 illustrates the patterning of the CAR layer 206 to provide the resist feature 214. The resist feature 214 may provide a masking element for forming a SRAF in the underlying chrome layer 204. The above described acid diffusion and/or quenching provides for an undercut 216 of the resist feature 214. In an exemplary embodiment, the resist feature 214 has a thickness T of 2500 Angstroms, a top width of W1 of 124 nm, a width W2 at the interface with the chrome layer 204 of 84 nm and an undercut width Wu of 20 nm. Thus, the aspect ratio of the photoresist feature 214 may be determined by the expression T/(W1−2*Wu). In the exemplary embodiment, the aspect ratio being 250/(124−2*20) or approximately 3.

The undercut may provide for decreased adhesion between the photoresist feature 214 and the chrome layer 204. With a decreased adhesion area (e.g., higher aspect ratio), the photoresist feature 214 may be more prone to defect such as lifting or peeling off the photomask 200. This undercut may become more critical as technology nodes shrink and the width of a SRAF is decreased.

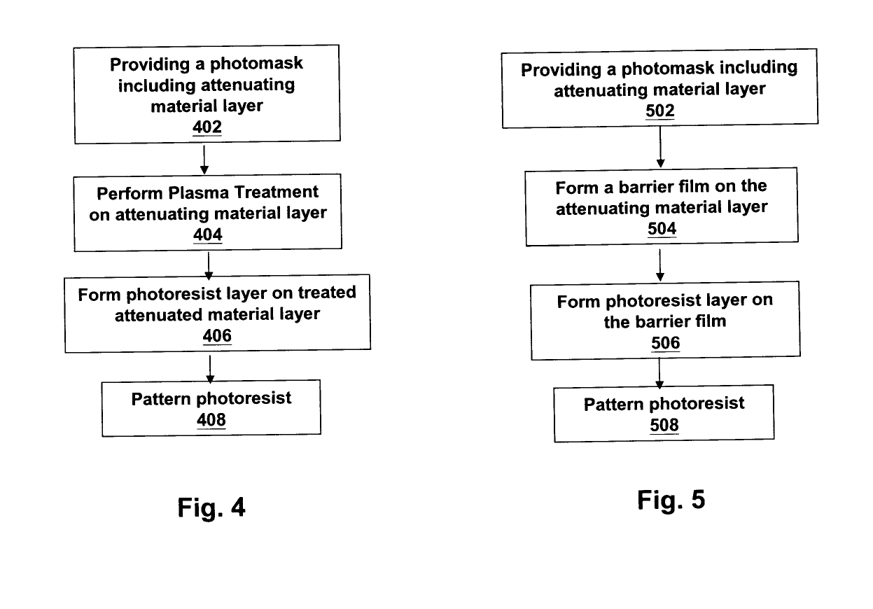

Referring now to FIG. 4, illustrated is a method 400 for fabricating a photomask. The method 400 may improve, in comparison to the above described photomask 200, the interface of a photoresist feature and an underlying layer on a photomask. The method 400 may provide for increased adhesion between a photoresist feature and a photomask, reduction of interaction between a photoresist feature and a photomask (e.g, decreased diffusion to/from a photoresist layer and one or more underlying layers of the photomask such as a chrome layer).

The method 400 begins at step 402 where a photomask including an attenuating layer is provided. In an embodiment, the attenuating layer includes chrome. The attenuating material may include other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. The attenuating layer may be formed on a transparent substrate. The transparent substrate may be substantially similar to the substrate 102, described above with reference to FIG. 1. In an embodiment, the transparent substrate includes quartz.

The method 400 then proceeds to step 404 where a plasma treatment is performed on the attenuating layer. In one embodiment, the plasma treatment uses an inlet gas of oxygen. In other embodiments, the plasma treatment uses argon, nitrogen, and/or other gases or combinations thereof. Still further examples of plasma gases include He, C, F, Cl, Br, Ne, Ar, and their compounds. The plasma (e.g., including ions and/or radicals such as O₂++) may physically impact the surface of the mask. The impact may roughen the surface of the mask, for example, the surface of an attenuating material (e.g., chrome) layer that is to be patterned. In an embodiment, the plasma treatment is implemented by a plasma tool such as a reactive ion etching (RIE) system, inductively coupled plasma (ICP) system, and/or other tools known in the art. The plasma process parameters such as flow rate, pressure, temperature, frequency, reaction power of the plasma chamber, duration, and the like may be determined to provide adequate roughening and/or formation of barrier film as described below. A plasma includes an ionized gas (e.g., where a significant percentage of the atoms or molecules are ionized) and the remaining proportion of electrons are free (e.g., such that the plasma may be electrically neutral medium of positive and negative particles).

In an embodiment, the plasma treatment provides to roughen the surface of the attenuating layer. The roughened surface may provide increased surface area for adhesion of an overlying layer (e.g., photoresist) to the attenuating layer (e.g., chrome). In an embodiment, the plasma treatment provides for a barrier film to be formed on the attenuating layer. The barrier film may include substantially similar to as described below with reference to the method 500 of FIG. 5. The plasma treatment may use a target including silicon. In an embodiment, the target is Si or SiO₂. Other targets are possible, for example, as determined by the desired barrier film.

The method 400 then proceeds to step 406 where a photoresist layer is formed on the photomask. The photoresist layer is formed on the treated surface of the attenuating material. In an embodiment, the photoresist layer directly interfaces the treated layer surface. For example, a photoresist layer may be formed directly on a roughened attenuating material layer surface (e.g., a treated chrome layer). In an embodiment, the photoresist layer directly interfaces to a barrier film formed by the plasma treatment of the attenuating material layer. The photoresist maybe positive tone or negative tone resist. The photoresist may include chemical amplification resist (CAR). The photoresist layer may be deposited on the photomask by spin-on technique.

The method 400 then proceeds to step 408 where the photoresist layer is patterned. The pattern may be provided selectively irradiating the photoresist layer. The radiation beam may be ultraviolet and/or can be extended to include other radiation beams such as ion beam, x-ray, extreme ultraviolet, deep ultraviolet, and other proper radiation energy. The patterned formed may be associated with resolution enhancement techniques (RET), for example, the pattern may be associated with a SRAF (e.g., provide a masking element for fabrication of a SRAF in an underlying area).

The method 400 may include further steps in the photolithography process not explicitly described such as soft baking and/or alignment procedures prior to exposing the resist. In an embodiment, the photolithography process further includes developing the photoresist (e.g., applying an aqueous tetra-methyl ammonium hydroxide (TMAH) solution), hard baking, and/or other processes known in the art. The photoresist may be removed by processes such as wet stripping or plasma ashing. In alternative embodiment, lithography processes such as e-beam may be used to pattern the photoresist layer.

Using the photoresist pattern formed (e.g., as a masking element), one or more underlying layers such as the attenuating material layer may be etched to form one or more SRAFs (scattering bars) on the photomask. The method 400 may continue to include stripping of the photoresist feature(s). In an embodiment, a barrier film formed by the plasma treatment is also removed. The attenuating material layer (e.g., chrome) may be further patterned to provide for main features such as, the main feature 120 described above in reference to FIG. 1. The main feature patterning may occur before, simultaneous to, and/or after the patterning of the photoresist to provide for RET features.

Referring now to FIG. 5, illustrated is a method 500 of fabricating a photomask. The method 500 may provide for increased adhesion between a photoresist layer/feature and a photomask, reduction of interaction between a photoresist layer and a photomask (e.g., decreased diffusion to/from a photoresist layer and one or more layers of the photomask such as, an underlying chrome layer).

The method 500 begins at step 502 where a photomask including an attenuating layer is provided. In an embodiment, the attenuating layer includes chrome. The attenuating material may include other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. The attenuating layer may be formed on a transparent substrate. The transparent substrate may be substantially similar to the substrate 102, described above with reference to FIG. 1. In an embodiment, the transparent substrate includes relatively defect-free quartz.

The method 500 then proceeds to step 504 where a barrier film is formed on the attenuating material layer. In an embodiment, the barrier film includes silicon oxide. Other embodiments of barrier film include silicon nitride, other films compositions including nitrogen and/or oxygen. In an embodiment, the barrier film may be between approximately 1 and 5 nanometers in thickness. The barrier film may be formed directly on a chrome layer of a photomask.

In an embodiment, the barrier film is formed by a plasma treatment of an attenuating material layer (e.g., chrome layer) of a photomask. In one embodiment, the plasma treatment uses an inlet gas of oxygen. The oxygen plasma (e.g., including ions and/or radicals such as O₂++) may physically impact the surface of the mask. In other embodiments, the plasma treatment utilizes argon, nitrogen, and/or other gases or combinations thereof. Still further examples of plasma gases include He, C, F, Cl, Br, Ne, Ar, and their compounds. The plasma treatment may use a target including silicon. In an embodiment, the target is Si or SiO₂. Other targets are possible as determined by the desired barrier film composition. In an embodiment, the plasma treatment is implemented by a plasma tool such as a reactive ion etching (RIE) system, inductively coupled plasma (ICP) systems, and/or other tools known in the art. The plasma process parameters such as pressure, frequency, reaction power of the plasma chamber may be determined to provide formation of barrier film.

In an embodiment, the plasma treatment may also provide to roughen the surface of the attenuating layer. The roughened surface may provided increased surface area for adhesion of the photoresist to the attenuating layer and/or the barrier film.

The method 500 then proceeds to step 506 where a photoresist layer is formed on the photomask and in particular on the barrier film. The photoresist maybe of positive tone or negative tone resist. The photoresist may be chemical amplification resist (CAR). The photoresist layer may be deposited on the photomask by spin-on technique.

The method 500 then proceeds to step 508 where the photoresist layer is patterned. The patterning may be provided by irradiating portions of the photoresist layer. A radiation beam may be ultraviolet and/or can be extended to include other radiation beams such as ion beam, x-ray, extreme ultraviolet, deep ultraviolet, and other proper radiation energy. The patterned formed may be associated with resolution enhancement techniques (RET), for example, the pattern may be associated with a SRAF.

In an embodiment, the forming of the photoresist pattern (e.g., photolithography process) also includes soft baking and/or mask aligning prior to exposing the resist. In an embodiment, the process further includes developing the photoresist (e.g., applying an aqueous tetra-methyl ammonium hydroxide (TMAH) solution), hard baking, and/or other processes known in the art. The photoresist may be removed by processes such as wet stripping or plasma ashing. In alternative embodiment, lithography processes such as e-beam may be used to pattern the photoresist layer.

Using the photoresist pattern formed, one or more underlying layers such as the attenuating material layer, may be etched to form one or more SRAF or scattering bars on the photomask. The method 500 may continue to provide for stripping of the photoresist pattern. In an embodiment, the barrier film is removed. The attenuating material layer (e.g., chrome) may be further patterned to provide for main features such as, the main feature 120 described above in reference to FIG. 1. The main feature patterning may occur before, simultaneous to, and/or after the patterning of the photoresist to provide for RET features.

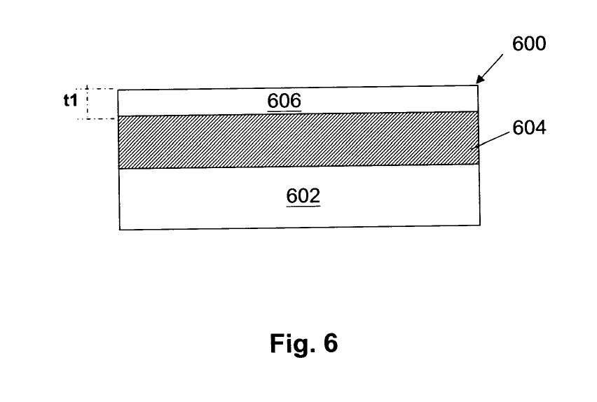

Referring now to FIG. 6, illustrated is a photomask 600 including a substrate 602, a chrome layer 604, and a barrier film 606. The photomask 600 may be provided using the method 400 and/or 500 or portions thereof. In an embodiment, the barrier film 606 is formed using a plasma treatment as described above. In an embodiment, the barrier film 606 includes silicon oxide. Examples of other materials include silicon nitride. In an embodiment, the barrier film 606 has a thickness t1 of approximately 1 to 5 nanometers. The substrate 602 may be substantially similar to the substrate 102 described above with reference to FIG. 1. In other embodiments, the chrome layer 604 may be substantially similar to chrome layer 204 described above with reference to FIG. 2. In alternative embodiments, the chrome layer 604 may include other attenuating materials in lieu of or in addition to chrome. In an embodiment, the surface of the chrome layer 604 interfacing with the barrier film 606 may be roughened by a plasma treatment.

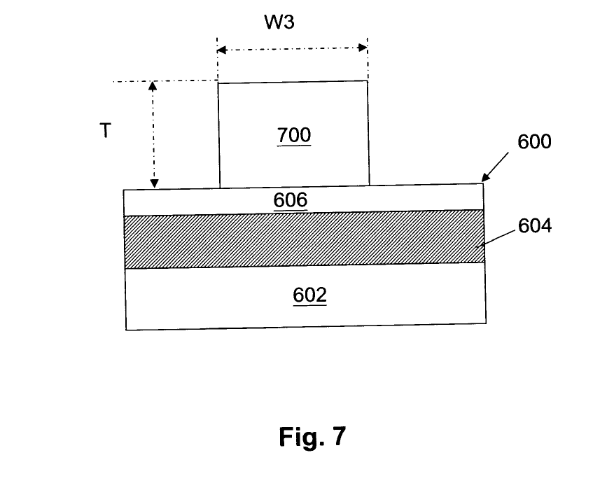

Referring now to FIG. 7, illustrated is the photomask 600 including the substrate 602, chrome layer 604, and barrier film 606 described above, and further comprising a photoresist feature 700. The photoresist feature may be formed as described above with reference to FIGS. 4 and/or 5. In an embodiment, the photoresist feature 700 is a masking element for fabricating a SRAF in the underlying chrome layer 604. The photoresist feature 700 illustrates reduced and/or eliminated undercutting in comparison with the photoresist feature 214 described above with reference to FIG. 3. The photoresist feature 700 includes a thickness T. The thickness T may be substantially similar to as described above with reference to the photoresist feature 214. The photoresist feature 700 further includes a width W3. The aspect ratio of the photoresist feature 700 is provided by the equation T/W3. In an embodiment, T is approximately equal to 2500 Angstroms and W3 is approximately equal to 124 nm, giving an aspect ratio of approximately 2.

In an embodiment, T is approximately 2500 Angstroms and W3 is approximately 124 nanometers. Thus, the aspect ratio of the photoresist feature 700 is approximately 2. This is comparison to the photoresist feature 214 of the FIG. 3. As described above in a previous embodiment, due to an undercut (e.g., Wu) on each side of the photoresist feature 214, the aspect ratio will be determined by T/(W1−2*Wu) and thus is greater than that of the photoresist feature 700. For example, in a comparative embodiment with substantially similar thicknesses, the photoresist feature 700 may have an aspect ratio of approximately 2 while a photoresist with an undercut, such as the photoresist feature 214, may have an aspect ratio of approximately 3. Therefore, illustrated is a reduction in the aspect ratio of a photoresist feature by reduction and/or elimination of an undercut of the feature.

Therefore provided is a photomask and method of forming such that provides for decreased diffusion of a base into the photoresist and therefore decrease in neutralization of a resist, for example, chemical amplification resist. Such decrease in neutralization may reduce undercutting in a photoresist feature. The photomask and method of forming such may also provide for decreased diffusion of an acid from a photoresist layer into an underlying attenuating material (e.g., chrome) layer. Such decreased diffusion may reduce a weakening of structure and/or composition of the chrome layer. Furthermore, the photomask and method for forming such may also provide for increased surface roughness of an attenuating material (e.g., chrome layer) such that increased surface area for adhesion with an overlying photoresist layer is provided. These techniques may be especially useful when the photoresist layer is to be patterned to form features such as SRAFs.

Although only a few exemplary embodiments of this invention have been described in detail above, those skilled in the art will readily appreciate that many modifications are possible in the exemplary embodiments without material departing from the novel teachings and advantages of this disclosure.

Thus, the present disclosure provides a method of fabricating a photomask. The method includes providing a substrate. A chrome layer is deposited on the substrate. A plasma treatment is performed on the chrome layer. A photoresist layer is formed on the treated chrome layer. In an embodiment, the photoresist layer may be patterned to form a masking element for a SRAF. The plasma treatment may roughen a surface of the photomask.

Also provided is a method of fabricating a photomask including providing a transparent substrate. A chrome layer is deposited on the transparent substrate. A barrier film is formed on the chrome layer. A photoresist layer is formed directly on the barrier film. In an embodiment, the barrier film is formed by a plasma treatment. In an embodiment, the barrier film is silicon oxide.

Also provided, is another method of fabricating a photomask. The method includes providing a substrate and depositing an attenuating material layer on the substrate. A plasma treatment is performed on the chrome layer to form a barrier film on the chrome layer. A photoresist layer is formed directly on the barrier film.

What is claimed is:

1. A method of fabricating a photomask, comprising:
providing a substrate;
forming a masking layer on the substrate;
performing a plasma treatment on the chrome layer; and
forming a photoresist layer on the treated chrome layer.

2. The method of claim 1, wherein forming the masking layer includes forming a chrome layer.

3. The method of claim 1, further comprising:
patterning the photoresist layer to form a pattern associated with a sub-resolution assist feature (SRAF).

4. The method of claim 1, wherein the plasma treatment roughens the surface of the masking layer.

5. The method of claim 1, wherein the plasma treatment forms a barrier film on the masking layer.

6. The method of claim 5, wherein the barrier film includes silicon oxide.

7. The method of claim 1, wherein the plasma treatment includes a plasma gas selected from the group consisting of oxygen, nitrogen, and argon.

8. The method of claim 2, further comprising:
patterning the photoresist layer; and
using the patterned photoresist layer as a masking element to etch the chrome layer, wherein the etching the chrome layer forms a sub-resolution assist feature (SRAF).

9. The method of claim 4, further comprising:
removing the photoresist layer; and
removing the barrier film.

10. The method of claim 1, wherein the patterned photoresist includes a feature having a length to width ratio of approximately 1:5.

11. A method of fabricating a photomask, comprising:
providing a transparent substrate;
depositing a chrome layer on the transparent substrate;
forming a barrier film on the chrome layer; and
forming a photoresist layer directly on the barrier film.

12. The method of claim 11, further comprising:
patterning the photoresist layer, wherein the pattern photoresist layer defines a sub-resolution assist feature (SRAF).

13. The method of claim 11, wherein the barrier film is silicon oxide.

14. The method of claim 11, wherein the barrier film includes a thickness between about 1 and 5 nanometers.

15. The method of claim 11, wherein the barrier film includes at least one of silicon oxide and silicon nitride.

16. The method of claim 15, further comprising:
patterning the photoresist layer to form a photoresist feature, wherein the photoresist feature is associated with providing a sub-resolution assist feature (SRAF).

17. The method of claim 16, wherein the photoresist feature exhibits substantially no undercutting.

18. A method of fabricating a photomask, comprising:
providing a substrate;
depositing an attenuating material layer on the substrate;
performing a plasma treatment on the chrome layer to form a barrier film on the chrome layer;
forming a photoresist layer directly on the barrier film; and
patterning the photoresist layer to provide a masking element for a sub-resolution assist feature.

19. The method of claim 18, wherein the photoresist layer includes chemical amplification resist (CAR).

20. The method of claim 18, wherein the barrier film is silicon oxide.
